(19) United States
(12) Patent Application Publication
(10) Pub. No.: US 2026/0357413 A1
(43) Pub. Date: Nov. 12, 2026

(54) DEPOSITION METHOD AND SPUTTERING APPARATUS

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/716,588

(22) Filed: Jun. 23, 2026

Related U.S. Application Data
(63) Continuation of application No. PCT/JP2025/000022, filed on Jan. 6, 2025.

(30) Foreign Application Priority Data
Jan. 29, 2024 (JP) 2024-010803

(51) Int. Cl. C23C 14/34; C23C 14/00; C23C 14/50; H01J 37/32; H01J 37/34; H10D 30/47; H10D 62/85; H10H 20/825; H10P 14/20; H10P 14/22; H10P 72/76

(52) U.S. Cl. CPC C23C 14/3492; C23C 14/0036; C23C 14/345; C23C 14/505; H01J 37/32715; H01J 37/3426; H01J 37/3464; H10D 30/475; H10D 62/8503; H10H 20/825; H10P 14/22; H10P 14/2904; H10P 14/2905; H10P 14/2921; H10P 14/2922; H10P 14/3416; H10P 72/7618; H01J 2237/20214; H01J 2237/332

(57) ABSTRACT

A fabrication method of a thin film includes: performing first sputtering on a sputtering target containing a Group 13 metal element in the presence of a sputtering gas to form a first layer containing the Group 13 metal element on a substrate; and performing second sputtering on the sputtering target in the presence of the sputtering gas to form a second layer containing the Group 13 metal element over the first layer. The energy of chemical species generated in the first sputtering and reaching the substrate is higher than that in the second sputtering.

### CROSS-REFERENCE TO RELATED APPLICATIONS

This application is a Continuation of International Patent Application No. PCT/JP 2025/000022, filed on Jan. 6, 2025, which claims the benefit of priority to Japanese Patent Application No. 2024-010803, filed on Jan. 29, 2024, the entire contents of which are incorporated herein by reference.

### FIELD

An embodiment of the present invention relates to a method for fabricating thin films by a sputtering method and a sputtering apparatus for realizing this method.

### BACKGROUND

In recent years, semiconductors containing nitrides of Group 13 metals, such as gallium nitride (GaN) and indium nitride (InN), have been applied to a variety of semiconductor devices including light-emitting diodes. Thin films of Group 13 metal nitrides are generally fabricated over a single crystalline substrate such as a silicon substrate, a sapphire substrate, and a silicon carbide substrate with an organic-metal chemical vapor deposition (MOCVD) method. Recently, it has been found that relatively highly crystalline thin films of Group 13 metal nitrides can be fabricated using a sputtering method (see, International Patent Publication No. 2022/259918, for example).

### SUMMARY

An embodiment of the present invention is a fabrication method of a thin film containing a Group 13 metal element. The fabrication method includes: performing first sputtering on a sputtering target containing a Group 13 metal element in the presence of a sputtering gas to form a first layer containing the Group 13 metal element on a substrate; and performing second sputtering on the sputtering target in the presence of the sputtering gas to form a second layer containing the Group 13 metal element over the first layer. The energy of chemical species generated in the first sputtering and reaching the substrate is higher than that in the second sputtering.

An embodiment of the present invention is a sputtering apparatus. The sputtering apparatus includes a target holder configured to hold a sputtering target and a substrate stage overlapping the target holder and configured to support a substrate. The substrate stage is further configured to rotate about a rotation axis which does not overlap a center of the sputtering target when the sputtering target is held by the target holder.

An embodiment of the present invention is a sputtering apparatus. The sputtering apparatus includes a target holder, a substrate stage, a first power source, and a second power source. The target holder is configured to hold a sputtering target. The substrate stage overlaps the target holder and is configured to support a substrate. The first power source and the second power source are configured to apply an alternating voltage between the sputtering target and the substrate stage when the sputtering target is held by the target holder. A frequency of the alternating voltage applied by the first power source is lower than that applied by the second power source.

An embodiment of the present invention is a sputtering apparatus. The sputtering apparatus includes a target holder configured to hold a sputtering target, a substrate stage overlapping the target holder, and a bias electrode over the substrate stage. The substrate stage and the bias electrode are configured to support a substrate. The bias electrode is electrically insulated from the substrate stage and is configured to be supplied with a potential different from a potential applied to the substrate stage.

### BRIEF DESCRIPTION OF DRAWINGS

FIG. 1 is a schematic cross-sectional view of a sputtering apparatus according to an embodiment of the present invention.

FIG. 2 is a schematic top view of a portion of a sputtering apparatus according to an embodiment of the present invention.

FIG. 3 is a schematic cross-sectional view explaining a fabrication method of thin films according to an embodiment of the present invention.

FIG. 4 is a schematic top view of a portion of a sputtering apparatus according to an embodiment of the present invention.

FIG. 5 is a schematic view explaining a fabrication method of thin films according to an embodiment of the present invention.

FIG. 6 is a schematic view explaining a fabrication method of thin films according to an embodiment of the present invention.

FIG. 7 is a schematic cross-sectional view of a portion of a sputtering apparatus according to an embodiment of the present invention.

FIG. 8 is a schematic view explaining a fabrication method of thin films according to an embodiment of the present invention.

FIG. 9 is a schematic cross-sectional view of a sputtering apparatus according to an embodiment of the present invention.

FIG. 10 is a schematic view explaining a fabrication method of thin films according to an embodiment of the present invention.

FIG. 11 is a schematic cross-sectional view of a light-emitting diode manufactured by utilizing a fabrication method of thin films according to an embodiment of the present invention.

FIG. 12 is a schematic cross-sectional view of a light-emitting diode manufactured by utilizing a fabrication method of thin films according to an embodiment of the present invention.

FIG. 13 is a schematic cross-sectional view of a transistor manufactured by utilizing a fabrication method of thin films according to an embodiment of the present invention.

FIG. 14 is a schematic cross-sectional view of a transistor manufactured by utilizing a fabrication method of thin films according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. When a plurality of structures the same as or similar to one another is represented, a reference number is used, and a hyphen and a natural number are added after the reference number when the plurality of structures is independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and claims, an expression that a structure is exposed from another structure means a mode where the portion of the structure is not covered by the other structure and includes a mode where the portion uncovered by the other structure is further covered by another structure. In addition, a mode expressed by this expression includes a mode where the structure is not in contact with the other structures.

### First Embodiment

In this embodiment, a sputtering apparatus according to an embodiment of the present invention and a method for fabricating a thin film using this sputtering apparatus are explained. In the following description, the method of forming a thin film containing a Group 13 metal element over a substrate is mainly described. However, the sputtering apparatus according to an embodiment of the present invention is not limited to the fabrication of thin films containing a Group 13 metal element, but can be used for fabricating insulating films, conducting films, and semiconductor films containing a variety of elements.

### 1. Sputtering Apparatus

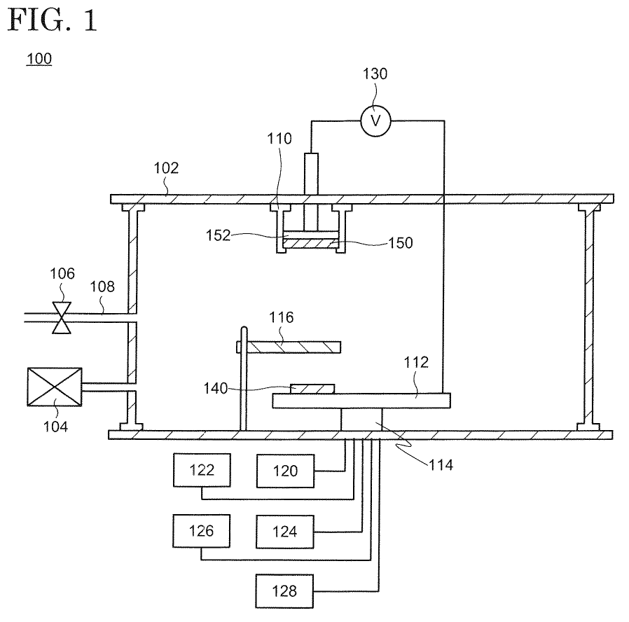

FIG. 1 shows a schematic cross-sectional view of the sputtering apparatus 100 according to the present embodiment. The sputtering apparatus 100 has a chamber 102, by which a space is provided for collisions of ions of elements contained in a sputtering gas such as argon, nitrogen, hydrogen, ammonia, and oxygen introduced into the chamber 102 with the sputtering target 150 and for deposition of the materials repelled from the sputtering target 150 by the collisions. The chamber 102 is provided with one or a plurality of load lock doors which is not illustrated, through which a substrate 140 is introduced into and removed from the chamber 102. The sputtering gas is introduced into the chamber 102 through one or a plurality of gas-supplying pipes 108 equipped with a valve 106. An exhaust device 104 for reducing the pressure in the chamber 102 is further connected to the chamber 102.

A target holder 110 for holding the sputtering target 150 and a backing plate 152 attached to the sputtering target 150 is provided in an upper portion of the chamber 102. Although one target holder 110 arranged in the chamber 102 is illustrated in FIG. 1, there is no restriction on the number of target holders 110, which may be, for example, equal to or more than 2 and equal to or less than 10.

A substrate stage 112 is provided in a lower portion of the chamber 102 for arranging the substrate 140 over which a thin film is to be formed. The substrate stage 112 is configured to rotate about an axis (rotation axis) parallel to the normal line of its main surface. The rotation axis of the substrate stage 112 does not overlap the center (or center of gravity, hereinafter the same is applied.) of the sputtering target 150 attached to the target holder 110 in the normal direction thereof. The rotation axis of the substrate stage 112 may or may not overlap with the sputtering target 150 in this direction. The substrate 140 is arranged so that the rotation axis of the substrate stage 112 does not overlap with the center of the substrate 140. Therefore, when the substrate stage 112 rotates with the substrate 140 supported over the substrate stage 112, the substrate 140 revolves about the rotation axis of the substrate stage 112. Although not illustrated, an electrostatic chuck may be further provided over the substrate stage 112 to secure the substrate 140.

A shutter 116 may be further provided between the substrate stage 112 and the target holder 110. The shutter 116 is configured to rotate or move in a plane approximately parallel to the main surface of the substrate stage 112. The shutter 116 is configured not to overlap the entire substrate stage 112 but to cover a portion of the substrate stage 112 even in a closed state. Thus, the shutter 116 is configured to cover a region shifted from the center of the substrate stage 112 in the closed state and is also configured to shield a portion of the material repelled from the sputtering target 150 to allow other portions of the material to reach the substrate stage 112 in the closed state. On the other hand, the shutter 116 is configured to allow most of the repelled material to reach the substrate stage 112 in the open state.

The sputter system 100 is further provided with a power source 130 for plasma generation which is connected to the substrate stage 112 and the backing plate 152. The power source 130 may be electrically connected to the substrate stage 112 via the chamber 102. The power source 130 may be an AC power source or a DC power source. In the case of an AC power source, the power source 130 may be a pulsed power source. The frequency of the AC power source may also be arbitrarily selected. For example, an HF power source of 3 MHz or higher and 30 MHz or lower, typically 13.56 MHz, may be used as the power source 130, or a VHF power source of 30 MHz or higher and 300 MHz lower may be used as the power source 130. A plasma is formed by the potential difference between the substrate stage 112 and the sputtering target 150 generated by the power source 130, and the sputtering gas is ionized by the plasma.

The sputtering apparatus 100 may be further provided with a power source 120 for an electrostatic chuck, a heater power source 122 for heating the substrate stage 112, a controller 124 for controlling a temperature of a cooling medium to be circulated in the substrate stage 112, a controller 126 for controlling the rotation of the substrate stage, and a bias power source 128 for supplying a potential to a bias electrode described below, and the like. These components are connected to the substrate stage 112, for example, via a shaft 114 supporting the substrate stage 112.

In the example shown in FIG. 1, the target holder 110 is arranged over the substrate stage 112, but the configuration of the sputtering apparatus 100 is not limited to this configuration. For example, the substrate stage 112 may be placed above the target holder 110, or the substrate stage 112 may be provided so that the normal line of the substrate 140 in the state supported by the substrate stage 112 is horizontal, while the target holder 110 opposes the substrate stage 112.

### 2. Fabrication Method of Thin Film

Hereinafter, a method of fabricating thin films using the aforementioned sputtering apparatus 100 is explained. Here, a method for fabricating a thin film containing a nitride of a Group 13 metal is explained as an example.

First, the sputtering target 150 formed over the backing plate 152 is set in the target holder 110. Examples of the materials contained in the sputtering target 150 include a gallium nitride-based compound semiconductor containing a Group 13 metal and nitrogen, such as gallium nitride, aluminum gallium nitride, and indium gallium nitride. The sputtering target 150 may contain a dopant such as silicon, germanium, magnesium, zinc, cadmium, and beryllium. Alternatively, gallium metal or indium metal (i.e., 0 valent gallium or indium) may be included in the sputtering target 150. When forming a thin film containing materials other than nitrides of Group 13 metals, a gallium phosphide-based compound semiconductor such as gallium phosphide, aluminum indium gallium phosphide, and indium gallium arsenide phosphide, an indium-based compound semiconductor such as indium phosphide, and a conductive oxide transmitting visible light such as indium-tin mixed oxide (ITO) and indium-zinc mixed oxide (IZO) may be used as the sputtering target 150. When the thin film to be fabricated does not contain a Group 13 metal element, the sputtering target 150 containing an element constituting the material to be contained in the thin film may be used as appropriate. For example, a metal (0-valent metal) such as aluminum, cobalt, chromium, molybdenum, niobium, titanium, tungsten, zinc, silver, gold, iron, and iridium or their alloys, an oxide such as aluminum oxide, copper oxide, chromium oxide, cesium oxide, magnesium oxide, titanium oxide, tungsten oxide, and strontium titanate, a carbide such as silicon carbide, a nitride such as aluminum nitride, chromium nitride, and silicon nitride, and a non-metallic element such as silicon, boron, carbon, and germanium are exemplified.

The substrate 140 is arranged over the substrate stage 112. There are no restrictions on the substrate 140 which can be used in the sputtering apparatus 100, and the substrate 140 may be a single-crystal substrate, a polycrystal substrate, or an amorphous substrate. For example, a single crystal silicon substrate, a polycrystalline silicon substrate, a sapphire substrate, a quartz substrate, and a silicon carbide substrate as well as a glass substrate and a plastic substrate may be used as the substrate 140. For example, a large rectangular amorphous glass substrate, also called mother glass, can be used as the substrate 140. Specifically, a glass substrate having a size of 2160 mm×2460 mm and called the 8th generation mother glass, a glass substrate having a size of 2400 mm×2800 mm and called the 9th generation mother glass, a glass substrate having a size of 2880 mm×3130 mm and called the 10th generation mother glass, or even a larger glass substrate may be used. The materials included in a plastic substrate include a polymer such as a polyimide, a polyamide, and a polycarbonate. The substrate 140 may be flexible.

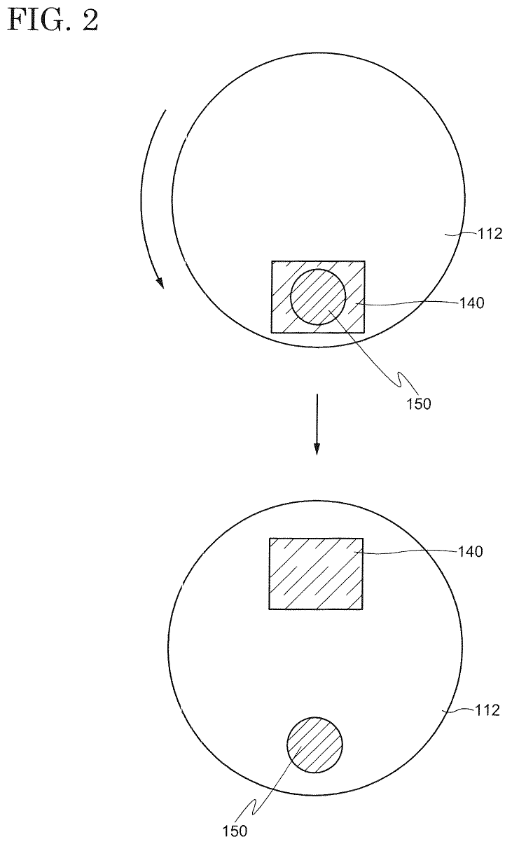

As shown in FIG. 2, the substrate 140 is arranged so that its center does not overlap the rotation axis of the substrate stage 112. The substrate 140 may be arranged so that the entire substrate 140 does not overlap the rotation axis of the substrate stage 112. This arrangement allows the substrate 140 to be revolved by the rotation of the substrate stage 112. As mentioned above, the rotation axis of the substrate stage 112 does not overlap the center of the sputtering target 150 held by the target holder 110 in the normal direction of its main surface. Therefore, as shown in FIG. 2, when the substrate stage 112 rotates, the substrate 140 is able to exist in a state where the substrate 140 overlaps the sputtering target 150 in the normal direction of the substrate stage 112 and a state where a part of or the entire substrate 140 does not overlap the sputtering target 150. Thus, as can be understood from FIG. 1 and FIG. 2, the distance between the substrate 140 and the sputtering target 150 varies as the substrate stage 112 rotates.

After that, the chamber 102 is depressurized using the exhaust device 104, and a sputtering gas is further introduced into the chamber 102 via the gas-supplying pipe 108. When a thin film containing a nitride of a Group 13 metal is formed, nitrogen gas is selected as the sputtering gas, for example. An inert gas such as argon may be supplied at the same time. Next, the power source 130 is used to generate a potential difference between the sputtering target 150 and the substrate stage 112. As a result, plasma is generated between the sputtering target 150 and the substrate stage 112, by which the elements contained in the sputtering gas are ionized. The ions of the elements contained in the sputtering gas are accelerated by the potential difference between the sputtering target 150 and the substrate stage 112 and collide with the sputtering target 150. The kinetic energy of the ions at this time repels the atoms or compounds in the sputtering target 150, and these atoms or compounds and/or the compounds produced by the reaction between these atoms and the elements in the sputtering gas are deposited over the substrate 140.

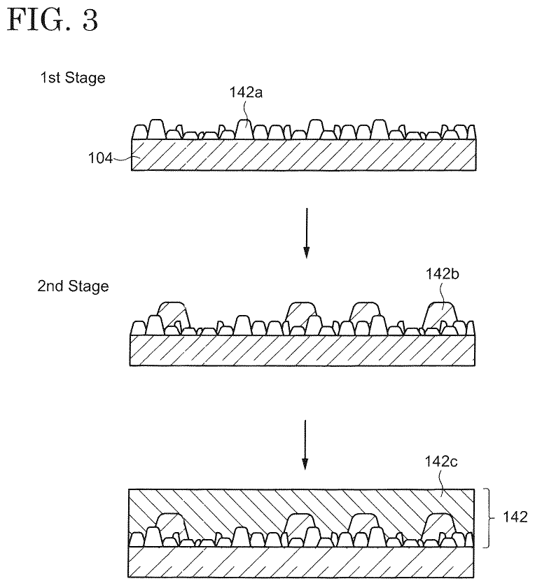

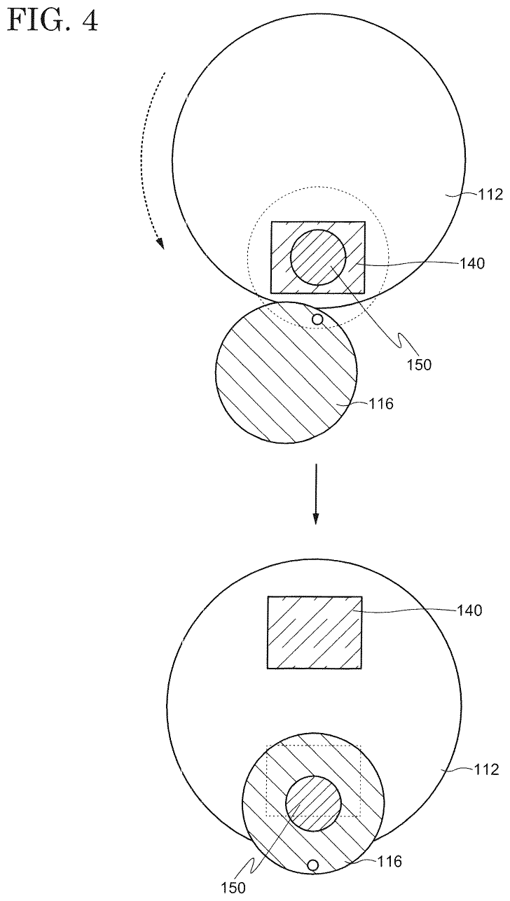

Here, the sputtering is performed in two stages. In the first sputtering, which is a first stage, a first layer 142a containing seed crystals of a Group 13 metal nitride is formed over the substrate 140 (FIG. 3). The seed crystals may be formed as an island shape over the substrate 140. When forming the seed crystals, the energy (kinetic energy) of the chemical species generated in the sputtering and reaching the substrate 140 is preferred to be high. Preferably, the energy of the chemical species is equal to or greater than 100 eV. Here, the chemical species include the atoms of Group 13 metals repelled from the sputtering target 150, the elements contained in the sputtering gas, and the compounds of Group 13 metals and the elements contained in the sputtering gas. The atoms of Group 13 metals may be ions. The elements included in the sputtering gas and the compounds of Group 13 metals and the elements included in the sputtering gas may be radicals or ions. The kinetic energy of these chemical species is taken away by collisions between the chemical species and other substances (e.g., the sputtering gas and its ions, radicals, and electrons). Therefore, the first stage is performed under the conditions where the distance between the substrate 140 and the sputtering target 150 is small to reduce the probability that the chemical species generated in the sputtering collide with other substances. Specifically, in the first stage, the substrate stage 112 is rotated as appropriate to allow the substrate 140 and the sputtering target 150 to overlap each other in the normal direction of the main surface of the substrate stage 112 as shown in FIG. 4, and the sputtering is performed in this state. When the shutter 116 is provided, the shutter 116 is opened. As a result, the flying distance for the chemical species to reach the substrate 140 is shortened, allowing the chemical species to reach the substrate 140 while maintaining a high energy. Accordingly, the migration of the chemical species on the surface of the substrate 140 is promoted, and crystal grains of a Group 13 metal nitride can effectively grow to form the first layer 142a containing columnar seed crystals with high crystallinity.

In the second sputtering, which is the second stage following the first stage, sputtering is performed under the conditions in which crystal growth of a Group 13 metal nitride first occurs three-dimensionally from the seed crystal surface, and then crystal growth occurs two-dimensionally. That is, in the early stage of the second stage, the crystal growth of a Group 13 metal nitride starts from the seed crystal surface and proceeds in both the normal direction of the substrate 140 and the direction perpendicular to the normal direction. However, the second sputtering is performed under the conditions in which the growth in the normal direction proceeds more rapidly. On the other hand, in the later stage of the second stage, the second sputtering is performed under the conditions where the crystal growth of a Group 13 metal nitride proceeds more rapidly in the direction perpendicular to the normal direction. Specifically, the second sputtering is performed under the conditions where the energy of the chemical species is lower than that in the first stage. Preferably, the second sputtering is performed so that the energy of the chemical species is lower than 100 eV. This is because, if the chemical species with a high energy is incident on the substrate after the seed crystal is formed, the formed seed crystal is damaged. Hence, the substrate stage 112 is rotated to move the substrate 140 away from the sputtering target 150 as shown by the dotted arrow in FIG. 4. Preferably, the second sputtering is performed after the substrate 140 is moved to a position where the substrate 140 does not overlap the sputtering target 150. As a result, the flying distance of the chemical species is increased, allowing the chemical species with a reduced energy to reach the substrate 140.

The crystal growth of a Group 13 metal nitride over the first layer 142a under the aforementioned conditions results in the three-dimensionally grown second layer 142b over the first layer 142a in the early stage of the second stage, and the three-dimensionally grown crystals from the seed crystals aggregate to result in large size crystals. Since the dislocations caused by the lattice mismatch between the seed crystals and the substrate 140 in this process do not extend in the growing thickness direction (upward direction on the paper) but are bent laterally so that the dislocations do not reach the device surface, high-quality crystals grow. Subsequently, the crystal growth proceeds two-dimensionally, resulting in the third layer 142c to cover the second layer 142b. Since the crystal growth in the second stage occurs from the surface of the first layer 142a including the seed crystals, the high crystallinity of the first layer 142a is reflected. Therefore, a thin film of a Group 13 metal nitride having high crystallinity can be formed over the entire substrate 140.

In addition, since the third layer 142c preferentially grows in the two-dimensional direction, a surface with high planarity can be obtained. Therefore, the planarity of a variety of films disposed over the third layer 142c is also improved. This feature contributes to the improvement of the characteristics of semiconductor devices fabricated using the film 142 composed of the first layer 142a to the third layers 142c. For example, when a light-emitting diode including the film 142 is fabricated, a quantum well structure having alternating layers of films with a thickness of approximately several nm may be formed to form an emission layer. Since the third layer 142c structuring the top layer of the film 142 has high planarity, the quantum well structure can be formed over a flat surface with few surface irregularities. Therefore, it is possible to manufacture a light-emitting diode having a quantum well structure with highly controlled structure, and as a result, a light-emitting diode with precisely controlled characteristics can be produced.

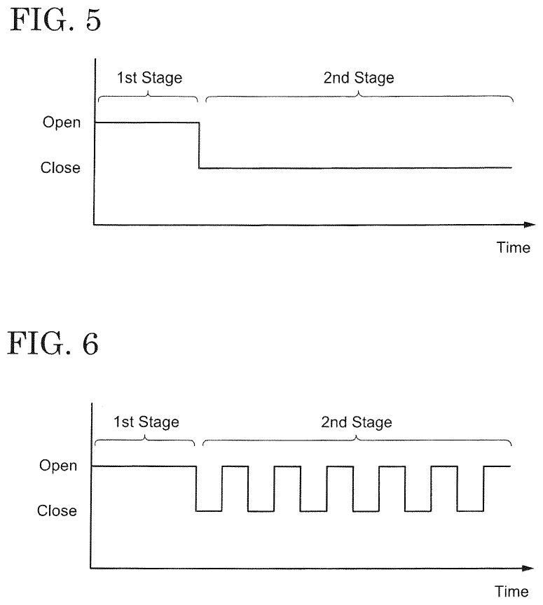

Note that the sputtering may be performed while continuously rotating the substrate stage 112. In this case, the first sputtering is performed in a state where the shutter 116 is opened as schematically shown in FIG. 5, so that the high-energy chemical species can reach the substrate 140 in the first stage. In the second stage, on the other hand, the shutter 116 is closed so that the high-energy chemical species cannot reach the substrate 140. Alternatively, the shutter 116 may be opened and closed intermittently in the second stage as shown in FIG. 6. That is, in the second stage, the shutter 116 may be closed when the substrate 140 overlaps the sputtering target 150 in the normal direction of the substrate 140 and opened when the substrate 140 does not overlap the sputtering target 150. In this case, the shutter 116 may be closed simultaneously at the time when the substrate 140 overlaps the sputtering target 150 or may be closed before the substrate 140 overlaps the sputtering target 150. Similarly, the shutter 116 may be opened simultaneously at the time when the substrate 140 no longer overlaps the sputtering target 150 or may be opened after the substrate 140 no longer overlaps the sputtering target 150. Sputtering while rotating the substrate stage 112 suppresses in-plane variations in the substrate 140 (e.g., in-plane variations in crystallinity and thickness of the second layer 142b and the third layer 142c).

Both the first sputtering and the second sputtering may be performed at a relatively low temperature equal to or higher than 500 °C and equal to or lower than 600 °C. Therefore, a glass substrate or the like with a relatively low melting point can be used as the substrate 140 in addition to a sapphire substrate, a silicon substrate, a quartz substrate, and a silicon carbide substrate with high melting points. This feature makes it possible to fabricate thin films containing a variety of materials in addition to a Group 13 metal nitride over a large-area substrate 140, thereby reducing the production cost of the thin films.

### Second Embodiment

In this embodiment, a modified example of the sputtering apparatus 100 described in the First Embodiment and a fabrication method of thin films using the same are explained. An explanation of the structures the same as or similar to those described in the First Embodiment may be omitted.

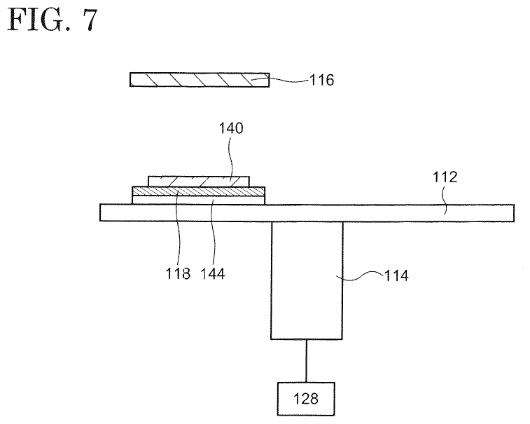

In this modified example, a bias electrode 118 is provided over the substrate stage 112 or over an electrostatic chuck (not illustrated) provided over the substrate stage 112 as shown in FIG. 7. When no electrostatic chuck is provided, the bias electrode 118 may be electrically insulated from the substrate stage 112 with an insulating film 144 or the like. The bias electrode 118 is connected to the bias power source 128 (see FIG. 1) and is configured to be supplied with a variable potential from the bias power source 128. The substrate 140 is positioned over the bias power source 128.

When forming a thin film using the sputter device 100, the power source 130 is controlled so that the potential applied to the sputtering target 150 is lower than the potential applied to the substrate stage 112 because the sputtering target 150 and the substrate stage 112 serve as a cathode and anode, respectively. On the other hand, a potential which is different from the potential applied to the sputtering target 150 and which is the same as or different from the potential applied to the substrate stage 112 is applied to the bias electrode 118. Specifically, a potential identical to the potential applied to the substrate stage 112 or a potential between the potentials applied to the sputtering target 150 and the substrate stage 112 is applied to the bias electrode 118. Therefore, the potential difference between the sputtering target 150 and the bias electrode 118 can be smaller than the potential difference between the sputtering target 150 and the substrate stage 112 by supplying a potential to the bias electrode 118. As a result, the acceleration voltage of the chemical species generated in the sputtering and reaching the substrate 140 can be reduced.

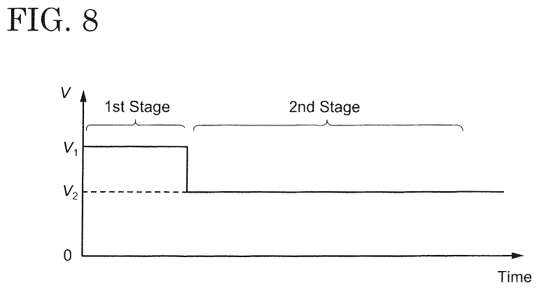

When forming a thin film using the sputtering apparatus 100 according to this modified example, the first sputtering and the second sputtering are performed so that the potential V₁ applied to the bias electrode 118 in the first stage is greater than the potential V₂ in the second stage as shown in FIG. 8. The potential V₁ may be the same as the potential applied to the substrate stage 112. These conditions cause the potential difference between the sputtering target 150 and the bias electrode 118 to be greater in the first sputtering compared to that in the second sputtering. Accordingly, the acceleration voltage of the chemical species generated in the sputtering and reaching the substrate 140 is much greater in the first sputtering, and the energy of the chemical species is higher in the first sputtering as compared to that in the second sputter. Therefore, the seed crystals are efficiently formed in the first sputtering as described in the First Embodiment. In addition, because damage from the chemical species with a high energy can be reduced in the second sputtering where the energy of the chemical species is lower, the second layer 142b and the third layer 142c which grow from the seed crystal surface also have high crystallinity and can grow in the three-dimensional directions and the two-dimensional directions, respectively.

### Third Embodiment

In this embodiment, a modified example of the sputtering apparatus 100 described in the First and Second Embodiments and a fabrication method of thin films using the same are explained. An explanation of the structures described in the First and Second Embodiments may be omitted.

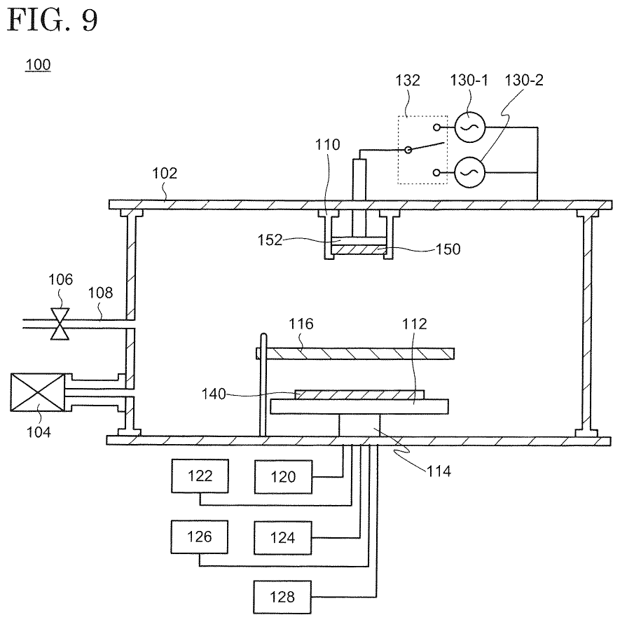

In the sputtering apparatus 100 according to this modified example, a plurality of power sources 130 with different characteristics is provided, and a potential difference is formed between the sputtering target 150 and the substrate stage 112 by the plurality of power sources 130. Specifically, a plurality of AC power sources with different frequencies (e.g., a first power source 130-1 and a second power source 132-2) are provided as shown in FIG. 9, and these power sources are switched by a switch 132. The frequency of the first power source 130-1 is, for example, equal to or higher than 3 MHz and equal to or lower than 30 MHz and is typically 13.56 MHz. In contrast, the frequency of the second power source 130-2 is higher than the first power source 130-1 and may be, for example, equal to or higher than 30 MHz and equal to or lower than 300 MHz.

In this modified example, the target holder 110 and the substrate stage 112 may be arranged so that the center of the sputtering target 150 and the center of the substrate 140 overlap on the normal line of the substrate stage 112. The shutter 116 may be configured to allow the chemical species to reach the substrate stage 112 in the open state but to overlap the entire substrate 140 on the normal line of the substrate stage 112 in the closed state to prohibit the chemical species from reaching the substrate stage 112.

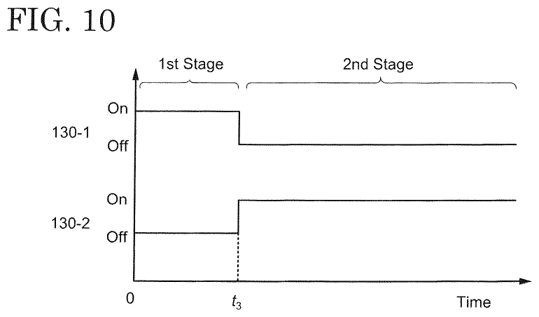

Since the energy of the ions of the sputtering gas ionized by the plasma increases with decreasing frequency of the AC voltage applied between the sputtering target 150 and the substrate stage 112, the energy of the chemical species generated in the sputtering and reaching the substrate 140 also increases. Therefore, the energy of the chemical species in the first sputtering can be increased compared with that in the second sputtering by using the first power source 130-1 in the first sputtering, which is the first stage, and the second power source 130-2 in the second sputtering, which is the second stage, as shown in FIG. 10. As a result, the seed crystals are formed efficiently in the first sputtering similar to the First and Second embodiments. In addition, because damage from the high-energy chemical species in the plasma is reduced in the second sputtering where the energy of the chemical species is lower, the second layer 142b and the third layer 142c growing from the seed crystal surface also have high crystallinity and can grow in the three-dimensional directions and the two-dimensional directions, respectively.

### Fourth Embodiment

In this embodiment, a modified example of the fabrication method of thin films using the sputtering apparatus 100 described in the First through Third embodiments is explained. An explanation of the structures the same as or similar to those described in the First to Third embodiments may be omitted.

As described above, the sputtering conditions are adjusted so that the energy of the chemical species generated in the sputtering and reaching the substrate 140 is higher in the first sputtering than that in the second sputtering in the fabrication method of thin films according to an embodiment of the present invention. The energy of the chemical species is also deprived by collisions with other substances. Therefore, the film formation may be performed so that the collision probability between the chemical species and other substances is lower in the first sputtering than that in the second sputtering. In other words, the film 142 may be formed under conditions where the mean free path of the chemical species is longer in the first sputtering than that in the second sputtering.

Specifically, the first sputtering and the second sputtering are performed so that the pressure of the sputtering gas in the first sputtering is lower than that in the second sputtering. For example, the pressure of the sputtering gas in the first sputtering may be set equal to or greater than 0.1 Pa and equal to or less than 1.0 Pa to the pressure of the sputtering gas in the second sputtering as a reference. The formation of the film 142 under such conditions allows the energy of the chemical species in the first sputtering to be increased compared with that in the second sputtering. As a result, the seed crystals are efficiently formed in the first sputtering similar to the First to Third Embodiments. Furthermore, the second layer 142b and the third layer 142c growing from the seed crystal surface in the second sputtering in which the energy of the chemical species is lower also have high crystallinity and can grow in three-dimensional directions and two-dimensional directions, respectively.

### Fifth Embodiment

The above-described sputtering apparatus 100 and the fabrication methods of thin films using the same can be applied to the manufacture of a variety of semiconductor devices. In this embodiment, a light-emitting diode and a transistor are described as examples of the semiconductor devices manufactured by utilizing the fabrication methods of thin films described in the First through Fourth embodiments. An explanation of the structures the same as or similar to those described in the First through Fourth embodiments may be omitted.

### (1) Light-Emitting Diode

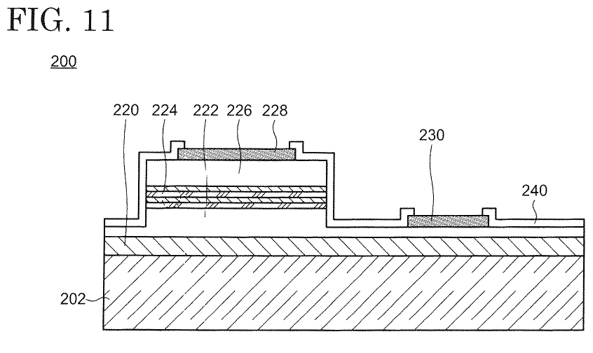

A schematic cross-sectional view of an example of a light-emitting diode 200 manufactured using the sputtering apparatus 100 is shown in FIG. 11. The light-emitting diode 200 has a substrate 202 and further has an undoped gallium nitride layer (hereinafter referred to as uGaN layer) 220 over the substrate 202. The light-emitting diode 200 further includes, over the uGaN layer 220, a laminate including an n-type cladding layer 222, a p-type cladding layer 226, and an emission layer 224 sandwiched between the n-type cladding layer 222 and the p-type cladding layer 226. In addition, the light-emitting diode 200 has an anode 228 and a cathode 230 provided over the p-type cladding layer 226 and the n-type cladding layer 222, respectively. The light-emitting diode 200 may further have a protective film 240 and the like over the anode 228 and the cathode 230 as an optional component. The uGaN layer 220 with high crystallinity and planarity can be fabricated over the substrate 202 by applying the fabrication method of the film 142 described in the First to Fourth embodiments.

The n-type cladding layer 222, the emission layer 224, and the p-type cladding layer 226 are configured to emit visible light when holes and electrons respectively injected from the anode 228 and cathode 230 are recombined. For example, the n-type cladding layer 222 may be configured to contain gallium nitride and a dopant imparting n-type conductivity such as silicon and germanium. On the other hand, the p-type cladding layer 226 may be configured to contain, for example, gallium nitride and a dopant imparting p-type conductivity such as magnesium, zinc, cadmium, and beryllium. The n-type cladding layer 222 and the p-type cladding layer 226 may each have a single-layer structure or a stacked-layer structure composed of a plurality of layers with different compositions.

The emission layer 224 may have a single-layer structure of indium gallium nitride, for example, or may have a quantum well structure as shown in FIG. 11. The quantum well structure is a structure of alternating layers of a plurality of thin films with different band gaps and extremely small thicknesses of 1 to 5 nm, and alternating layers of indium gallium nitride and gallium nitride, alternating layers of indium gallium arsenide phosphide (GaInAsP) and indium phosphide (InP), alternating layers of aluminum indium arsenide (AlInAs) and indium gallium indium arsenide (InGaAs), and the like are exemplified.

The anode 228 and the cathode 230 inject holes and electrons into the p-type cladding layer 226 and the n-type cladding layer 222, respectively. As the anode 228, a thin film of a metal such as palladium, nickel, and gold, a stack thereof, or a conductive oxide transmitting visible light such as indium-tin mixed oxide (ITO) and indium-zinc mixed oxide (IZO) may be used, for example. A metal such as aluminum, titanium, gold, silver, and indium, stacked films thereof, or an alloy thereof may be used as the cathode 230. Both the anode 228 and the cathode 230 may have a single-layer structure or may be a laminate of a plurality of films having different compositions.

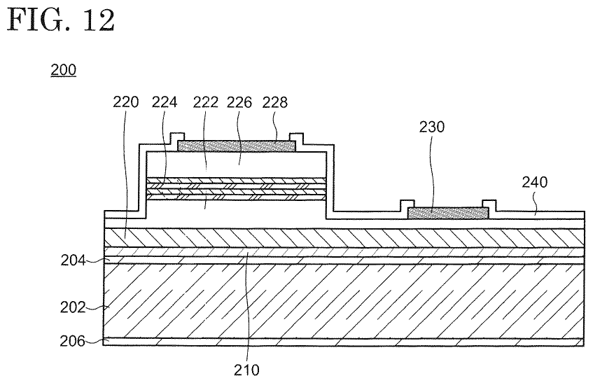

The substrate 202 corresponds to the substrate 140 of the First through Third Embodiments and is selected from a high-melting point substrate such as a quartz substrate, a single crystalline silicon substrate, a single crystalline sapphire, and a silicon carbide substrate. However, the substrate 202 may also be an amorphous glass substrate including alkali-free glass and the like. In this case, a buffer layer 210 is provided over the substrate 202 over which the uGaN layer 220 is formed as shown in FIG. 12. It is preferable to provide an overcoat 204 and/or an undercoat 206 between the substrate 202 and the buffer layer 210 and/or under the substrate 202, respectively.

The buffer layer 210 improves the adhesion between the substrate 202 and the uGaN layer 220 to prevent deformation (warpage) of the substrate 202 under the high temperature conditions during the manufacture of the light-emitting diode 200. Furthermore, the buffer layer 210 contributes to promoting the crystallization of the uGaN layer 220 provided thereover in the c-axis direction. As described above, the fabrication method of the film 142 described in the First through Fourth Embodiments is used for the uGaN layer 220. Therefore, even if an amorphous glass substrate is used as the substrate 202, the buffer layer 210 promotes the growth of the seed crystals in the c-axis direction to result in the first layer 142a with aligned crystal-growth directions. Therefore, the crystallinity of the entire uGaN layer 220 including the first layer 142a and each layer provided thereover can also be improved. This feature allows the production of the light-emitting diode 200 with excellent characteristics. The buffer layer 210 may be configured to include aluminum nitride, indium aluminum nitride, aluminum gallium nitride, aluminum oxide, aluminum oxynitride, titanium nitride, titanium, aluminum, silver, nickel, copper, and the like. The buffer layer 210 may also have a single-layer structure or a stacked-layer structure.

The overcoat 204 is provided over the substrate 202 so as to be in contact with the substrate 202. It is possible to prevent the diffusion of impurities such as alkali metal ions contained in the substrate 202 by providing the overcoat 204. The overcoat 204 may be a single film or a plurality of films containing a silicon-containing inorganic compound such as silicon oxide and silicon nitride. The undercoat 206 suppresses desorption of water and the like from the substrate 202 under the high temperature conditions during the manufacture of the light-emitting diode 200, prevents impurities including oxygen from entering the uGaN layer 220, the n-type cladding layer 222, the emission layer 224, the p-type cladding layer 226, and the like, and also prevents warpage of the substrate 202 due to the difference in thermal expansion coefficient between the substrate 202 and the uGaN layer 220. A film containing aluminum nitride, a film containing aluminum oxide, or a laminate of these films may be used as the undercoat 206.

The protective film 240 is a component for preventing impurities such as oxygen and water from entering the light-emitting diode 200 and is composed of one or a plurality of films containing a silicon-containing inorganic compound such as silicon oxide and silicon nitride. The protective film 240 has openings to expose the anode 228 and the cathode 230, and wirings which are not illustrated are electrically connected to the anode 228 and cathode 230 using these openings.

Each layer structuring the aforementioned light-emitting diode 200 is formed with a sputtering method using the sputtering apparatus 100 and the deposition method in accordance with an embodiment of the present invention. Therefore, deposition at a high temperature required by epitaxial growth using a MOCVD method and the like is not required, and the light-emitting diode 200 can be fabricated without deformation of or damage to the substrate 202 even when the substrate 202 containing amorphous glass is used.

### (2) Transistor

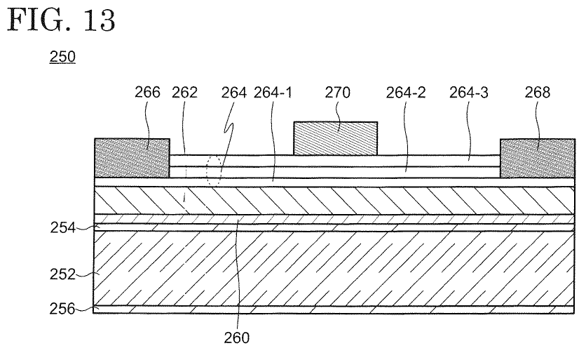

A schematic cross-sectional view of an example of a transistor 250 manufactured using the sputtering apparatus 100 is shown in FIG. 13. The transistor 250 shown in FIG. 13 is a high electron-mobility field-effect transistor and includes a substrate 252 corresponding to the substrate 140 as well as the buffer layer 260 and an active layer (also called an electron-travelling layer) 262 over the substrate 252. The transistor 250 also has an electron-supplying layer 264 over the active layer 262 as well as a gate electrode 270 and a pair of terminals (first terminal 266 and second terminal 268) located over the active layer 262 and electrically connected to the active layer 262 and the electron-supplying layer 264. The first terminal 266 and the second terminal 268 may be in contact with the active layer 262 or may be in contact with the active layer 262 through the electron-supplying layer 264 as shown in FIG. 13. The transistor 250 further includes the overcoat 254 and the undercoat 256. Hereinafter, these components will be described below. However, since the structures of the substrate 252, the overcoat 254, the undercoat 256, and the buffer layer 260 are similar to those of the corresponding components of the light-emitting diode 200 described above, their explanations will be omitted. When a single crystalline substrate with a high melting point is used as the substrate 202, the overcoat 254, the undercoat 256, and the buffer layer 260 may not be provided.

The stack of the active layer 262 and the electron-supplying layer 264 forms a source/drain current path when the transistor 250 is driven. The active layer 262 and the electron-supplying layer 264 include a Group 13 metal element and a Group 15 element. For example, the active layer 262 and the electron-supplying layer 264 may each include a gallium nitride-based or gallium arsenide-based compound semiconductor. In one example, the active layer 262 may be configured to include undoped gallium nitride, while the electron-supplying layer 264 may be composed of a first electron-supplying layer 264-1 including undoped aluminum gallium nitride, a second electron-supplying layer 264-2 including undoped gallium nitride, and a third electron-supplying layer 264-3 including p-type indium gallium nitride. The active layer 262 may be formed by applying the fabrication method of the film 142 described in the First through Fourth Embodiments.

The first terminal 266, the second terminal 268, and the gate electrode 270 include a metal such as aluminum, gold, silver, tantalum, molybdenum, titanium, and copper or an alloy containing one or a plurality of the above metals. Although not illustrated, a gate insulating film may be provided between the electron-supplying layer 264 and the gate electrode 270 as an optional component. The gate insulating film includes, for example, a silicon-containing inorganic compound such as silicon oxide and silicon nitride or a so-called high-k material such as hafnium silicate, zirconium silicate, hafnium oxide, and zirconium oxide. Although these components may also be formed by a vacuum evaporation method, an electron beam evaporation method, or a CVD method, they can be formed with a sputtering method using the sputtering apparatus 100 described above.

In addition to the active layer 262, the electron-supplying layer 264 may also be formed using a sputtering method within the sputtering apparatus 100 described above. Therefore, deposition at a high temperature required by the epitaxial growth using a MOCVD method is not required, and these layers can be formed without deformation of or damage to the substrate 252 even if the substrate 252 containing amorphous glass is used. Furthermore, even when an amorphous substrate is used as the substrate 252, the buffer layer 210 promotes the growth of the seed crystals in the c-axis direction, and the active layer 262 with aligned crystal growth directions can be formed. Therefore, the crystallinity of the entire active layer 262 including the first layer 142a as well as the electron-supplying layer 264 provided thereover can also be improved, which allows the production of the transistor 250 having excellent characteristics.

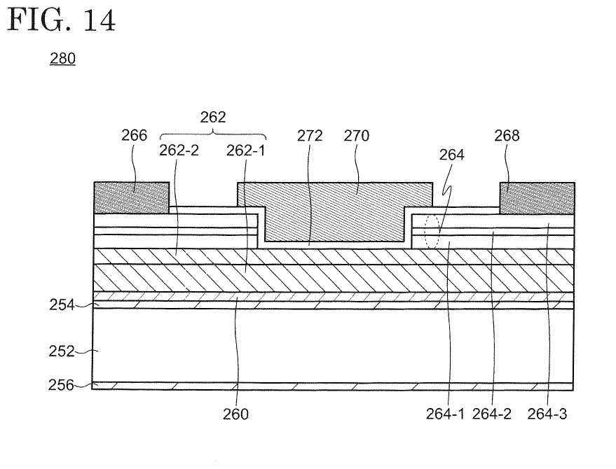

The transistor manufactured using the sputtering apparatus 100 is not limited to the transistor 250 with the structure shown in FIG. 13. For example, the active layer 262 may have a two-layer structure as in the transistor 280 shown in FIG. 14. In this case, the active layer 262 may be composed of, for example, a first active layer 262-1 including undoped gallium nitride and a second active layer 262-2 including undoped aluminum gallium nitride. In the formation of the first active layer 262-1, the fabrication methods of the film 142 described in the First through Fourth Embodiments are applied. There is also no restriction on the structure of the electron-supplying layer 264. For example, the electron-supplying layer 264 may be structured as a stack of a first electron-supplying layer 264-1 including undoped gallium nitride, a second electron-supplying layer 264-2 including n-type gallium nitride, and a third electron-supplying layer 264-3 including undoped gallium nitride. The gate insulating film 272 is provided between the active layer 262 and the gate electrode 270. The gate insulating film 272 may be configured to include aluminum oxide or the silicon-containing inorganic compound and the high-k material described above.

In the transistor 280, not only the buffer layer 260, the gate insulating film 272, the gate electrode 270, the first terminal 266, and the second terminal 268, but also the extremely thin active layer 262 which determines the characteristics thereof can be formed with a sputtering method using the sputtering apparatus 100 described above. Since the first active layer 262-1 formed over the substrate 252 is fabricated by applying the deposition method according to an embodiment of the present invention as described above, the planarity of the top surface thereof is high. Therefore, the planarity of each layer formed over the first active layer 262-1 is also improved, and as a result, the structure of each layer can be precisely controlled. This feature contributes to the mass production of the transistor 280 with highly controlled characteristics.

Although explanation is omitted, the aforementioned sputtering apparatus 100 and the deposition method using the same can be used not only for fabricating the above-mentioned semiconductor devices, but also for fabricating a variety of configurations such as wirings, terminals, capacitor elements, and electrodes necessary for driving semiconductor devices.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

1. A fabrication method of a thin film containing a Group 13 metal element comprising:
performing first sputtering on a sputtering target containing a Group 13 metal element in the presence of a sputtering gas to form a first layer containing the Group 13 metal element on a substrate; and
performing second sputtering on the sputtering target in the presence of the sputtering gas to form a second layer containing the Group 13 metal element over the first layer,
wherein the energy of chemical species generated in the first sputtering and reaching the substrate is higher than that in the second sputtering.

2. The fabrication method according to claim 1,
wherein the chemical species is at least one of an atom of the Group 13 metal element, an element included in the sputtering gas, and a compound containing the Group 13 metal element and the element.

3. The fabrication method according to claim 1,
wherein the sputtering gas contains nitrogen, and
the first layer and the second layer further contain nitrogen.

4. The fabrication method according to claim 3,
wherein the sputtering gas further contains argon.

5. The fabrication method according to claim 1,
wherein the sputtering target further contains nitrogen.

6. The fabrication method according to claim 1,
wherein the Group 13 metal element is selected from gallium and indium.

7. The fabrication method according to claim 1,
wherein the energy of the chemical species in the first sputtering is equal to or greater than 100 eV.

8. The fabrication method according to claim 1,
wherein a pressure of the sputtering gas in the first sputtering is lower than that in the second sputtering.

9. The fabrication method according to claim 1,
wherein a distance between the sputtering target and the substrate in the first sputtering is shorter than that in the second sputtering.

10. The fabrication method according to claim 1,
wherein the first sputtering is performed in a state where the sputtering target overlaps the substrate, and
the second sputtering is performed in a state where the sputtering target does not overlap the substrate.

11. The fabrication method according to claim 1,
wherein the substrate is arranged to overlap the sputtering target and is arranged over a substrate stage configured to rotate about a rotation axis which does not overlap a center of the sputtering target.

12. The fabrication method according to claim 11,
wherein the first sputtering and the second puttering are performed while rotating the substrate stage,
the first sputtering is performed in a state where a shutter arranged between the substrate state and the sputtering target is opened,
the second sputtering is performed in a state where the shutter is closed, and
the shutter is configured so as not to overlap the sputtering target in an opened state but to overlap the sputtering target in a closed state.

13. The fabrication method according to claim 1,
wherein the first sputtering and the second sputtering are performed while applying an alternating voltage between the substrate and the sputtering target, and
a frequency of the alternating voltage in the first sputtering is lower than that in the second sputtering.

14. The fabrication method according to claim 1,
wherein the substrate is arranged over a bias electrode over the substrate stage, and
the first sputtering and the second sputtering are performed so that a potential difference between the sputtering target and the bias electrode in the first sputtering is greater than that in the second sputtering.

15. The fabrication method according to claim 1,
wherein the substrate is selected from a glass substrate, a single crystalline silicon substrate, a sapphire substrate, and a silicon carbide substrate.

16. A sputtering apparatus comprising:
a target holder configured to hold a sputtering target; and
a substrate stage overlapping the target holder and configured to support a substrate,
wherein the substrate stage is further configured to rotate about a rotation axis which does not overlap a center of the sputtering target when the sputtering target is held by the target holder.

17. A sputtering apparatus comprising:
a target holder configured to hold a sputtering target;
a substrate stage overlapping the target holder and configured to support a substrate; and
a first power source and a second power source configured to apply an alternating voltage between the sputtering target and the substrate stage when the sputtering target is held by the target holder, and
wherein a frequency of the alternating voltage applied by the first power source is lower than that applied by the second power source.

18. A sputtering apparatus comprising:
a target holder configured to hold a sputtering target;
a substrate stage overlapping the target holder; and
a bias electrode over the substrate stage,
wherein the substrate stage and the bias electrode are configured to support a substrate;
the bias electrode is electrically insulated from the substrate stage and is configured to be supplied with a potential different from a potential applied to the substrate stage.

19. The sputtering apparatus according to claim 16, further comprising a shutter between the target holder and the substrate stage,
wherein the shutter is configured to exist in a state where the substrate arranged over the substrate stage is exposed from the shutter and a state where the substrate is covered by the shutter when the substrate is rotated in a state where the shutter is closed.
